(19) United States
(12) Patent Application Publication
(10) Pub. No.: US 2025/0261353 A1
(43) Pub. Date: Aug. 14, 2025

(54) MAGNETORHEOLOGICAL FLUID SYSTEM FOR COOLING AND ELECTROMAGNETIC INTERFERENCE SHIELDING

(71) Applicant: Toyota Motor Engineering & Manufacturing North America, Inc., Plano, TX (US)

(72) Inventors: Yanghe Liu, Ann Arbor, MI (US); Jae Seung Lee, Ann Arbor, MI (US); Ercan Mehmet Dede, Ann Arbor, MI (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 18/441,054

(22) Filed: Feb. 14, 2024

(51) Int. Cl. H05K 9/00; H05K 7/20

(52) U.S. Cl. CPC H05K 9/0081; H05K 7/20272

(57) ABSTRACT

Systems and methods described herein relate to implementing magnetorheological fluid-based cooling or shielding strategies. In one embodiment, a method includes storing magnetorheological fluid; pumping the magnetorheological fluid; cooling the magnetorheological fluid; and distributing the magnetorheological fluid within an array of channels within a structure to provide cooling or electromagnetic interference shielding to a vehicular component.

### CROSS REFERENCE TO RELATED APPLICATION

This invention is related to U.S. patent application Ser. No. ______, filed same day as the present application, titled “Thermomagnetic Cooling Using Magnetorheological Fluid,” the disclosures of which are incorporated herein by reference and made a part hereof.

### TECHNICAL FIELD

The subject matter described herein relates, in general, to strategies for cooling and electromagnetic interference shielding, and, more particularly, to using a magnetorheological fluid system to provide such cooling and electromagnetic interference shielding.

### BACKGROUND

Wireless charging generates heat and electromagnetic interference. One approach to managing heat with respect to wireless charging is limit power transference to keep temperatures low. With respect to electromagnetic interference, vehicles may use metal shielding to block signals or ferrite bars whose magnetic flux alters the radiation of signals.

### SUMMARY

In one embodiment, a system is disclosed. The system includes a reservoir to store magnetorheological fluid, a pump, a heat exchanger, and a structure having an array of channels to distribute the magnetorheological fluid that provides cooling or electromagnetic interference shielding to a vehicular component.

In one embodiment, a non-transitory computer-readable medium including instructions that when executed by one or more processors cause the one or more processors to perform one or more functions is disclosed. The instructions include instructions to store magnetorheological fluid, pump the magnetorheological fluid, cool the magnetorheological fluid, and distribute the magnetorheological fluid within an array of channels within a structure to provide cooling or electromagnetic interference shielding to a vehicular component.

In one embodiment, a method for implementing magnetorheological fluid-based cooling or shielding strategies is disclosed. In one embodiment, the method includes storing magnetorheological fluid, pumping the magnetorheological fluid, cooling the magnetorheological fluid; and distributing the magnetorheological fluid within an array of channels within a structure to provide cooling or electromagnetic interference shielding to a vehicular component.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of a vehicle within which systems and methods disclosed herein may be implemented.

FIG. 2 illustrates one embodiment of an MR fluid system that is associated with implementing magnetorheological fluid-based cooling or shielding strategies.

FIG. 3 illustrates one embodiment of a cloud computing environment within which the systems and methods described herein may operate.

FIG. 4 illustrates one example of an MR fluid system.

FIG. 5A illustrates one example of an MR fluid structure for cooling or EMI shielding.

FIG. 5B illustrates an additional example of an MR fluid structure for cooling or EMI shielding.

FIG. 6 illustrates one example of a method for cooling and electromagnetic interference (EMI) shielding.

### DETAILED DESCRIPTION

Systems, methods, and other embodiments associated with a magnetorheological (MR) fluid system are described herein to provide cooling and electromagnetic interference (EMI) shielding. MR fluids are a class of smart materials characterized by fast, tunable, and reversible changes in their rheological properties under the application of magnetic fields. MR fluids consist of dispersions of micron sized particles of magnetizable materials dispersed in a liquid. Application of magnetic fields results in the magnetization of the dispersed particles, which consequently experience attractive forces, giving rise to the formation of particle structures that oppose the flow.

Rather than using ferrite for EMI shielding, MR fluids distributed within an array of channels may be used to provide EMI shielding. In addition, the MR fluid may also be used to provide cooling, such as for transmission coils that may run hot while charging. Accordingly, an MR fluid-based system is described herein that may provide cooling or EMI shielding to vehicle components.

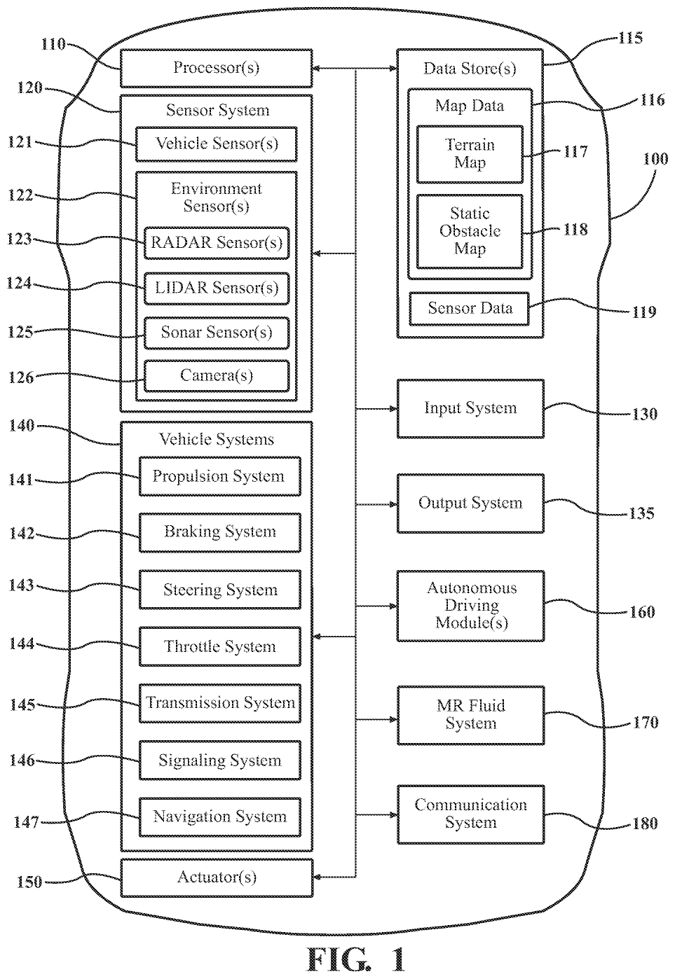

Referring to FIG. 1, an example of a vehicle 100 is illustrated. As used herein, a “vehicle” is any form of motorized transport. In one or more implementations, vehicle 100 is an automobile. While arrangements will be described herein with respect to automobiles, it will be understood that embodiments are not limited to automobiles. In some implementations, vehicle 100 may be any robotic device or form of motorized transport that, for example, includes sensors to perceive aspects of the surrounding environment, and thus benefits from the functionality discussed herein associated with MR fluid-based cooling or shielding strategies. As a further note, this disclosure generally discusses vehicle 100 as traveling on a roadway with surrounding vehicles, which are intended to be construed in a similar manner as vehicle 100 itself. That is, the surrounding vehicles may include any vehicle that may be encountered on a roadway by vehicle 100.

Vehicle 100 also includes various elements. It will be understood that in various embodiments it may not be necessary for vehicle 100 to have all of the elements shown in FIG. 1. Vehicle 100 may have any combination of the various elements shown in FIG. 1. Further, vehicle 100 may have additional elements to those shown in FIG. 1. In some arrangements, vehicle 100 may be implemented without one or more of the elements shown in FIG. 1. While the various elements are shown as being located within vehicle 100 in FIG. 1, it will be understood that one or more of these elements may be located external to vehicle 100. Further, the elements shown may be physically separated by large distances. For example, as discussed, one or more components of the disclosed system may be implemented within a vehicle while further components of the system are implemented within a cloud-computing environment or other system that is remote from vehicle 100.

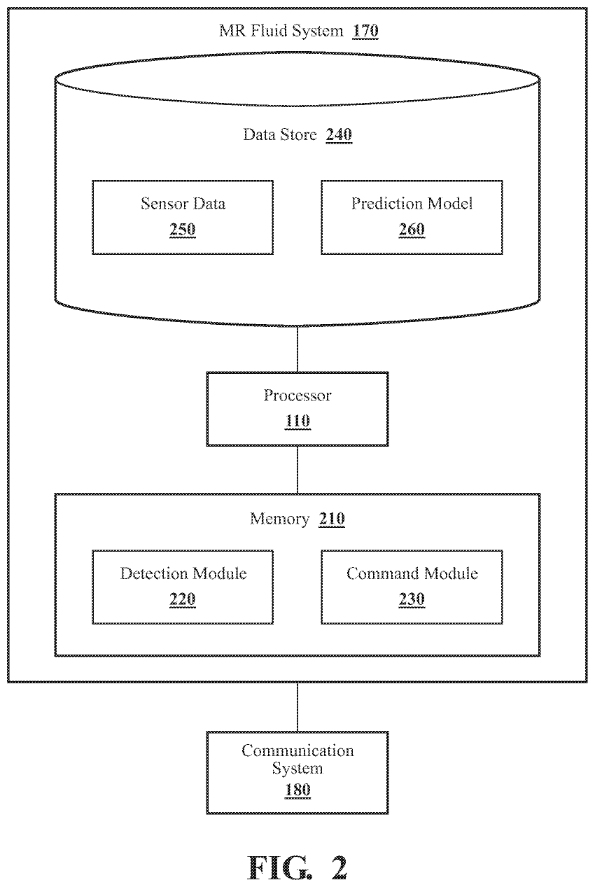

Some of the possible elements of vehicle 100 are shown in FIG. 1 and will be described along with subsequent figures. However, a description of many of the elements in FIG. 1 will be provided after the discussion of FIGS. 2-6 for purposes of brevity of this description. Additionally, it will be appreciated that for simplicity and clarity of illustration, where appropriate, reference numerals have been repeated among the different figures to indicate corresponding or analogous elements. In addition, the discussion outlines numerous specific details to provide a thorough understanding of the embodiments described herein. Those of skill in the art, however, will understand that the embodiments described herein may be practiced using various combinations of these elements. In either case, vehicle 100 includes a MR fluid system 170 that is implemented to perform methods and other functions as disclosed herein relating to implementing cooling or EMI shielding strategies. As will be discussed in greater detail subsequently, MR fluid system 170, in various embodiments, is implemented partially within vehicle 100 and as a cloud-based service. For example, in one approach, functionality associated with at least one module of MR fluid system 170 is implemented within vehicle 100 while further functionality is implemented within a cloud-based computing system.

With reference to FIG. 2, one embodiment of MR fluid system 170 of FIG. 1 is further illustrated. MR fluid system 170 is shown as including processor(s) 110 from vehicle 100 of FIG. 1. Accordingly, processor(s) 110 may be a part of MR fluid system 170, MR fluid system 170 may include a separate processor from processor 110(s) of vehicle 100, or MR fluid system 170 may access processor 110(s) through a data bus or another communication path. In one embodiment, MR fluid system 170 includes memory 210, which stores detection module 220 and command module 230. Memory 210 is a random-access memory (RAM), read-only memory (ROM), a hard-disk drive, a flash memory, or other suitable memory for storing detection module 220 and command module 230. Detection module 220 and command module 230 are, for example, computer-readable instructions that when executed by processor(s) 110 cause processor(s) 110 to perform the various functions disclosed herein.

MR fluid system 170 as illustrated in FIG. 2 is generally an abstracted form of MR fluid system 170 as may be implemented between vehicle 100 and a cloud-computing environment. Accordingly, MR fluid system 170 may be embodied at least in part within a cloud-computing environment to perform the methods described herein.

With reference to FIG. 2, detection module 220 generally includes instructions that function to control processor(s) 110 to receive data inputs from one or more sensors of vehicle 100. The inputs are, in one embodiment, observations of one or more objects in an environment proximate to vehicle 100, other aspects about the surroundings, or both. As provided for herein, detection module 220, in one embodiment, acquires sensor data 250 that includes at least camera images. In further arrangements, detection module 220 acquires sensor data 250 from further sensors such as radar 123, LiDAR 124, and other sensors as may be suitable for identifying vehicles, locations of the vehicles, lane markers, crosswalks, traffic signs, vehicle parking areas, road surface types, curbs, vehicle barriers, and so on. In one embodiment, detection module 220 may also acquire sensor data 250 from one or more sensors that allow for implementing MR fluid-based cooling or shielding strategies.

Accordingly, detection module 220, in one embodiment, controls the respective sensors to provide sensor data 250. Additionally, while detection module 220 is discussed as controlling the various sensors to provide sensor data 250, in one or more embodiments, detection module 220 may employ other techniques to acquire sensor data 250 that are either active or passive. For example, detection module 220 may passively sniff sensor data 250 from a stream of electronic information provided by the various sensors to further components within vehicle 100. Moreover, detection module 220 may undertake various approaches to fuse data from multiple sensors when providing sensor data 250, from sensor data acquired over a wireless communication link (e.g., v2v) from one or more of the surrounding vehicles, or from a combination thereof. Thus, sensor data 250, in one embodiment, represents a combination of perceptions acquired from multiple sensors.

In addition to locations of surrounding vehicles, sensor data 250 may also include, for example, odometry information, GPS data, or other location data. Moreover, detection module 220, in one embodiment, controls the sensors to acquire sensor data about an area that encompasses 360 degrees about vehicle 100, which may then be stored in sensor data 250. In some embodiments, such area sensor data may be used to provide a comprehensive assessment of the surrounding environment around vehicle 100. Of course, in alternative embodiments, detection module 220 may acquire the sensor data about a forward direction alone when, for example, vehicle 100 is not equipped with further sensors to include additional regions about the vehicle or the additional regions are not scanned due to other reasons (e.g., unnecessary due to known current conditions).

Moreover, in one embodiment, MR fluid system 170 includes a database 240. Database 240 is, in one embodiment, an electronic data structure stored in memory 210 or another data store and that is configured with routines that may be executed by processor(s) 110 for analyzing stored data, providing stored data, organizing stored data, and so on. Thus, in one embodiment, database 240 stores data used by the detection module 220 and command module 230 in executing various functions. In one embodiment, database 240 includes sensor data 250 along with, for example, metadata that characterize various aspects of sensor data 250. For example, the metadata may include location coordinates (e.g., longitude and latitude), relative map coordinates or tile identifiers, time/date stamps from when separate sensor data 250 was generated, and so on.

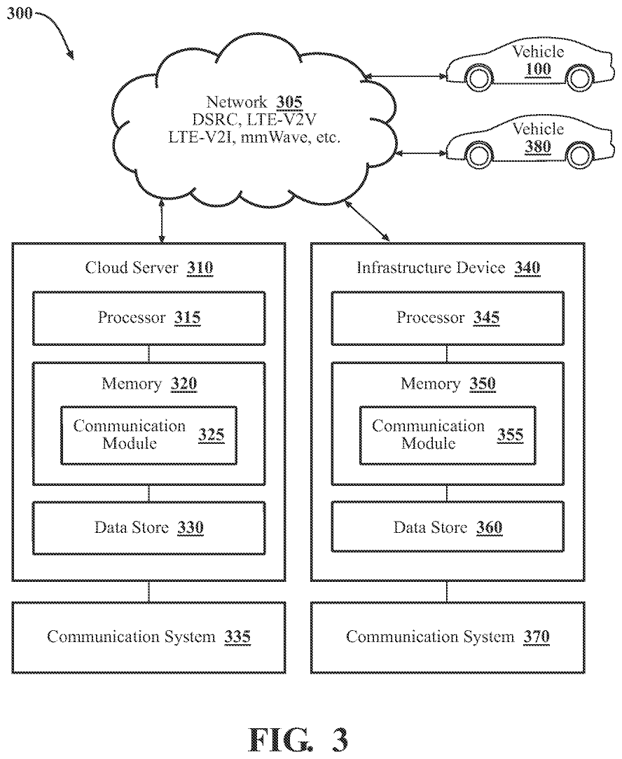

In one embodiment, command module 230 generally includes instructions that function to control the processor(s) 110 or collection of processors in the cloud-computing environment 300 as shown in FIG. 3 for implementing cooling or EMI shielding strategies.

With reference to FIG. 3, vehicle 100 may be connected to a network 305, which allows for communication between vehicle 100 and cloud servers (e.g., cloud server 310), infrastructure devices (e.g., infrastructure device 340), other vehicles (e.g., vehicle 380), and any other systems connected to network 305. With respect to network 305, such a network may use any form of communication or networking to exchange data, including but not limited to the Internet, Directed Short Range Communication (DSRC) service, LTE, 5G, millimeter wave (mmWave) communications, and so on.

Cloud server 310 is shown as including a processor 315 that may be a part of MR fluid system 170 through network 305 via communication unit 335. In one embodiment, cloud server 310 includes a memory 320 that stores a communication module 325. Memory 320 is a random-access memory (RAM), read-only memory (ROM), a hard-disk drive, a flash memory, or other suitable memory for storing communication module 325. Communication module 325 is, for example, computer-readable instructions that when executed by processor 315 causes processor 315 to perform the various functions disclosed herein. Moreover, in one embodiment, cloud server 310 includes database 330. Database 330 is, in one embodiment, an electronic data structure stored in a memory 320 or another data store and that is configured with routines that may be executed by processor 315 for analyzing stored data, providing stored data, organizing stored data, and so on.

Infrastructure device 340 is shown as including a processor 345 that may be a part of MR fluid system 170 through network 305 via communication unit 370. In one embodiment, infrastructure device 340 includes a memory 350 that stores a communication module 355. Memory 350 is a random-access memory (RAM), read-only memory (ROM), a hard-disk drive, a flash memory, or other suitable memory for storing communication module 355. Communication module 355 is, for example, computer-readable instructions that when executed by processor 345 causes processor 345 to perform the various functions disclosed herein. Moreover, in one embodiment, infrastructure device 340 includes a database 360. Database 360 is, in one embodiment, an electronic data structure stored in memory 350 or another data store and that is configured with routines that may be executed by processor 345 for analyzing stored data, providing stored data, organizing stored data, and so on.

Accordingly, in addition to information obtained from sensor data 250, MR fluid system 170 may obtain information from cloud servers (e.g., cloud server 310), infrastructure devices (e.g., infrastructure device 340), other vehicles (e.g., vehicle 380), and any other systems connected to network 305. For example, cloud servers (e.g., cloud server 310) may be used to perform the same tasks as described herein with respect to command module 230. For example, infrastructure device 340 may detect within its coverage area a vehicle in need of wireless charging, such that infrastructure device 340 may determine when the vehicle should engage MR fluid-based cooling or shielding strategies prior to the start of wireless charging.

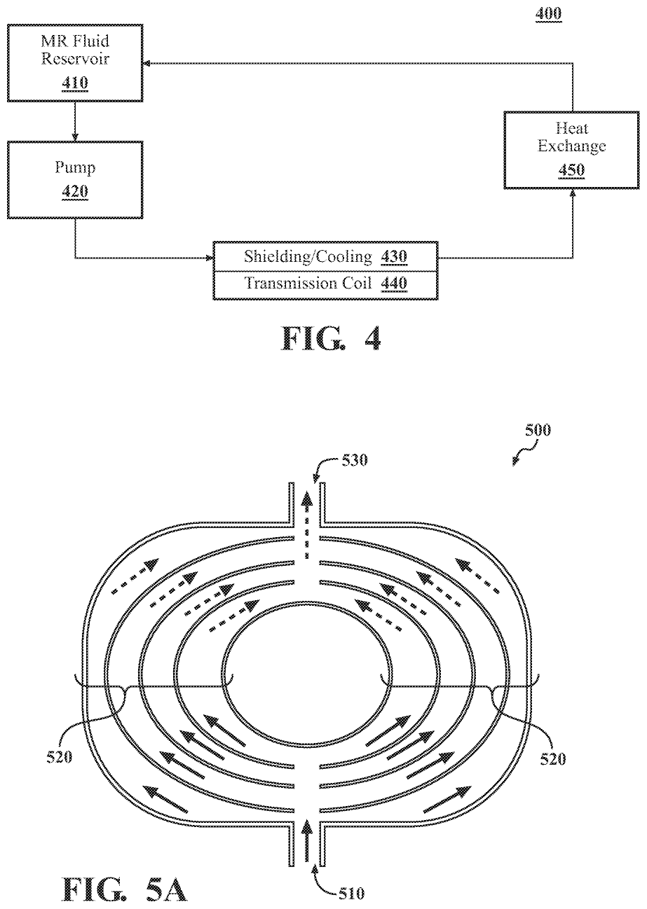

With respect to FIG. 4, an example of MR fluid system 400 is shown, which may be operated as part of MR fluid system 170. MR fluid system 400 may contain MR fluid reservoir 410 for storing MR fluid. Pump 420 may be connected to MR fluid reservoir 410 to provide pressurized flow of MR fluid within MR fluid system 400. From pump 420, MR fluid may be sent to shielding/cooling 430, wherein the MR fluid may provide EMI shielding, cooling, or both in relation to transmission coil 440. Transmission coil 440 may be a coil for sending or receiving wireless energy. Shielding/cooling 430 may then be connected to heat exchange 450, which may act to exchange heat from the MR fluid to another medium (e.g., air, water, antifreeze). Heat exchange 450 may then be connected to MR fluid reservoir 410 for the return of MR fluid.

With respect to the above example, the components of MR fluid system 400 may be arranged in a different order. For example, heat exchange 450 may precede shielding/cooling 430. In some embodiments, additional shielding/cooling components may be added to provide cooling or shielding to various modules. For example, sensor system 120 of vehicle 100 may have sensors requiring cooling or EMI shielding. In such an embodiment, MR fluid may be delivered to a structure containing a channel array. A channel array provides a number of channels through which the MR fluid can flow so as to provide cooling or EMI shielding.

With respect to heat exchange 450, cooling of the MR fluid may be performed using radiators, condensers, heat exchangers, and so on. For example, MR fluid may be stored at a temperature of 65 degrees C. and arrive at heat exchange 450 at 105 degrees C. for cooling. Such cooling may then be performed using radiators, condensers, heat exchangers to exchange such heat from the MR fluid to another medium, such as air, water, ethylene glycol, a mix of water and ethylene glycol, etc.

In some embodiments, MR fluid system 400 may be integrated into other cooling systems of vehicle 100. For example, MR fluid reservoir 410, pump 420, heat exchange 450, or a combination thereof may also be part of a battery cooling system, a motor cooling system, etc.

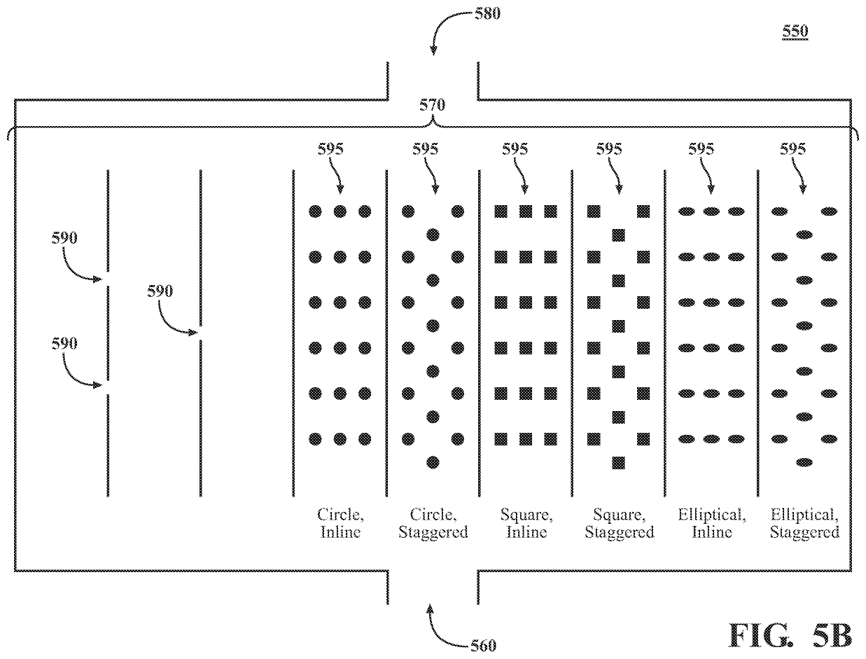

With respect to FIG. 5A, an example of a shield/cooling structure 500 is shown, which may serve as shielding/cooling 430 in MR fluid system 400. As shown, shield/cooling structure 500 has an input port 510 that receives MR fluid and distributes it to channel array 520. The MR fluid may then travel through channel array 520 until it arrives at output port 530 and is returned to an MR fluid system. As shown in FIG. 5A, channel array 520 may be configured to provide EMI shielding or cooling to a circular ring-shaped area (e.g., corresponding to the rear area of a transmission coil). In some embodiments, each channel of the channel array may be formed so as to carry more or less MR fluid within a shielding/cooling structure. For example, with respect to shielding/cooling structure 500, the inner channels of channel array 520 may have a larger fluid capacity than the outer channels of channel array 520 (e.g., wider channels toward the center, thinner channels further away), such that greater cooling, EMI shielding, or both occur toward the center of shield/cooling structure 500. Such an approach may be advantageous for example where thermal and magnetic effects on the MR fluid causes differences in the performance of the MR fluid in each channel (e.g., inner channels receiving more heat may be made larger to compensate for thermally induced paramagnetism within the MR fluid). Accordingly, within a channel array, some channels may be narrow or others wider in order to distribute cooling, EMI shielding, or both in a desired manner. In addition, a channel array may have channels that are longer, shorter, or routed differently so as to distribute cooling, EMI shielding, or both in a desired manner. For example, in some embodiments, a channel array within a shielding/cooling structure may be designed to provide EMI isolation for a sensor where allowances must be made within the channel array of shielding/cooling structure for the passage of couplers to the sensors. In some embodiments, a shielding/cooling structure may be used to provide cooling for non-electronic components of vehicle 100 (e.g., regenerative braking systems).

With respect to FIG. 5B, an example of a shield/cooling structure 550 is shown, which may serve as shielding/cooling 430 in MR fluid system 400. As shown, shield/cooling structure 550 has an input port 560 that receives MR fluid and distributes it to channel array 570. The MR fluid may then travel through channel array 570 until it arrives at output port 580 and is returned to an MR fluid system. Channel array 570 may be configured to provide EMI shielding or cooling to an area beneath or above shield/cooling structure 550. Shield/cooling structure 550 may be designed in a manner similar to shield/cooling structure 500 as described above. In addition, shield/cooling structure 550 may incorporate channel crossovers 590 and channel pins 595 within channel array 570, various examples of which are shown in FIG. 5B. For example, as shown in FIG. 5B, boundaries between channels within channel array 570 may be partially omitted to form one or more channel crossovers 590, each of which may allow for the flow of MR fluid across a crossover between channels. Such crossovers may be advantageous in preventing a potential overheating event from damaging channel array 570. Similarly, as shown in FIG. 5B, intrusions of the boundary material of a channel may be made to form one or more channel pins 595. Such intrusions forming one or more channel pins 595 may partially or fully divide a channel (e.g., a raised bump within a channel vs. a cylindrical column attached between opposing sides of a channel). In some embodiments, channel pins 595 may be formed using specific geometric forms, such as channel pins having square, rectangular, or ellipsoidal cross-sections. In addition, channel pins 595 may be placed within a channel to form inline or staggered formations of channel pins 595, which may repeat in a period or aperiodic manner.

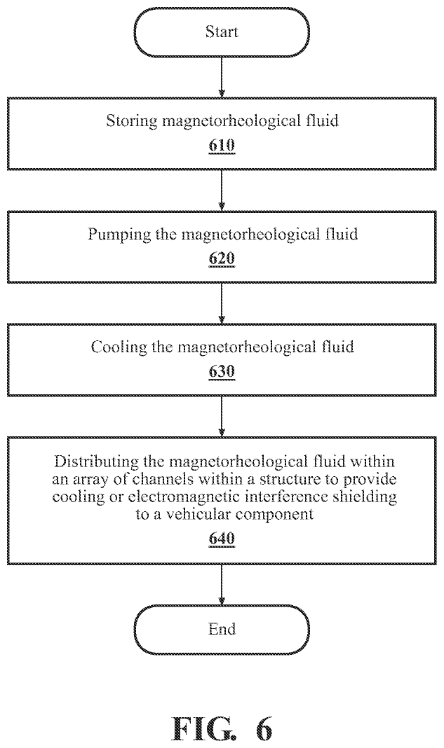

FIG. 6 illustrates a flowchart of a method 600 that is associated with MR fluid-based cooling or shielding strategies. Method 600 will be discussed from the perspective of the MR fluid system 170 of FIGS. 1 and 2. While method 600 is discussed in combination with the MR fluid system 170, it should be appreciated that the method 600 is not limited to being implemented within MR fluid system 170 but is instead one example of a system that may implement method 600.

At 610, MR fluid system 170 may store the magnetorheological fluid in vehicle 100, such as in MR fluid reservoir 410. In some embodiments, MR fluid reservoir 410 may be equipment with temperature sensors, pressure sensors, and so on to determine the state of the MR fluid.

At 620, MR fluid system 170 may pump the magnetorheological fluid (e.g., throughout MR fluid system 400).

At 630, MR fluid system 170 may cool the magnetorheological fluid (e.g., through a radiator, condenser, heat exchanger, etc.)

At 640, MR fluid system 170 may distribute the magnetorheological fluid within an array of channels within a structure to provide cooling or electromagnetic interference shielding to a vehicular component. In some embodiments the array of channels may be comprised of different lengths, different diameters, designed to provide maximum cooling toward the center of the structure, designed to provide maximum electromagnetic interference shielding toward the center of the structure, etc. In some embodiments the vehicular component may be a sensor or a non electronic component. In some embodiments, the vehicular component may be paired with the structure so as to allow for conductive cooling.

FIG. 1 will now be discussed in full detail as an example environment within which the system and methods disclosed herein may operate. In some instances, vehicle 100 is configured to switch selectively between various modes, such as an autonomous mode, one or more semi-autonomous operational modes, a manual mode, etc. Such switching may be implemented in a suitable manner, now known, or later developed. “Manual mode” means that all of or a majority of the navigation/maneuvering of the vehicle is performed according to inputs received from a user (e.g., human driver). In one or more arrangements, vehicle 100 may be a conventional vehicle that is configured to operate in only a manual mode.

In one or more embodiments, vehicle 100 is an autonomous vehicle. As used herein, “autonomous vehicle” refers to a vehicle that operates in an autonomous mode. “Autonomous mode” refers to using one or more computing systems to control vehicle 100, such as providing navigation/maneuvering of vehicle 100 along a travel route, with minimal or no input from a human driver. In one or more embodiments, vehicle 100 is either highly automated or completely automated. In one embodiment, vehicle 100 is configured with one or more semi-autonomous operational modes in which one or more computing systems perform a portion of the navigation/maneuvering of the vehicle along a travel route, and a vehicle operator (i.e., driver) provides inputs to the vehicle to perform a portion of the navigation/maneuvering of vehicle 100 along a travel route.

Vehicle 100 may include one or more processors 110. In one or more arrangements, processor(s) 110 may be a main processor of vehicle 100. For instance, processor(s) 110 may be an electronic control unit (ECU). Vehicle 100 may include one or more data stores 115 for storing one or more types of data. Data store(s) 115 may include volatile memory, non-volatile memory, or both. Examples of suitable data store(s) 115 include RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. Data store(s) 115 may be a component of processor(s) 110, or data store 115 may be operatively connected to processor(s) 110 for use thereby. The term “operatively connected,” as used throughout this description, may include direct or indirect connections, including connections without direct physical contact.

In one or more arrangements, data store(s) 115 may include map data 116. Map data 116 may include maps of one or more geographic areas. In some instances, map data 116 may include information or data on roads, traffic control devices, road markings, structures, features, landmarks, or any combination thereof in the one or more geographic areas. Map data 116 may be in any suitable form. In some instances, map data 116 may include aerial views of an area. In some instances, map data 116 may include ground views of an area, including 360-degree ground views. Map data 116 may include measurements, dimensions, distances, information, or any combination thereof for one or more items included in map data 116. Map data 116 may also include measurements, dimensions, distances, information, or any combination thereof relative to other items included in map data 116. Map data 116 may include a digital map with information about road geometry. Map data 116 may be high quality, highly detailed, or both.

In one or more arrangements, map data 116 may include one or more terrain maps 117. Terrain map(s) 117 may include information about the ground, terrain, roads, surfaces, other features, or any combination thereof of one or more geographic areas. Terrain map(s) 117 may include elevation data in the one or more geographic areas. Terrain map(s) 117 may be high quality, highly detailed, or both. Terrain map(s) 117 may define one or more ground surfaces, which may include paved roads, unpaved roads, land, and other things that define a ground surface.

In one or more arrangements, map data 116 may include one or more static obstacle maps 118. Static obstacle map(s) 118 may include information about one or more static obstacles located within one or more geographic areas. A “static obstacle” is a physical object whose position does not change or substantially change over a period of time and whose size does not change or substantially change over a period of time. Examples of static obstacles include trees, buildings, curbs, fences, railings, medians, utility poles, statues, monuments, signs, benches, furniture, mailboxes, large rocks, hills. The static obstacles may be objects that extend above ground level. The one or more static obstacles included in static obstacle map(s) 118 may have location data, size data, dimension data, material data, other data, or any combination thereof, associated with it. Static obstacle map(s) 118 may include measurements, dimensions, distances, information, or any combination thereof for one or more static obstacles. Static obstacle map(s) 118 may be high quality, highly detailed, or both. Static obstacle map(s) 118 may be updated to reflect changes within a mapped area.

Data store(s) 115 may include sensor data 119. In this context, “sensor data” means any information about the sensors that vehicle 100 is equipped with, including the capabilities and other information about such sensors. As will be explained below, vehicle 100 may include sensor system 120. Sensor data 119 may relate to one or more sensors of sensor system 120. As an example, in one or more arrangements, sensor data 119 may include information on one or more LIDAR sensors 124 of sensor system 120.

In some instances, at least a portion of map data 116 or sensor data 119 may be located in data stores(s) 115 located onboard vehicle 100. Alternatively, or in addition, at least a portion of map data 116 or sensor data 119 may be located in data stores(s) 115 that are located remotely from vehicle 100.

As noted above, vehicle 100 may include sensor system 120. Sensor system 120 may include one or more sensors. “Sensor” means any device, component, or system that may detect or sense something. The one or more sensors may be configured to sense, detect, or perform both in real-time. As used herein, the term “real-time” means a level of processing responsiveness that a user or system senses as sufficiently immediate for a particular process or determination to be made, or that enables the processor to keep up with some external process.

In arrangements in which sensor system 120 includes a plurality of sensors, the sensors may work independently from each other. Alternatively, two or more of the sensors may work in combination with each other. In such an embodiment, the two or more sensors may form a sensor network. Sensor system 120, the one or more sensors, or both may be operatively connected to processor(s) 110, data store(s) 115, another element of vehicle 100 (including any of the elements shown in FIG. 1), or any combination thereof. Sensor system 120 may acquire data of at least a portion of the external environment of vehicle 100 (e.g., nearby vehicles).

Sensor system 120 may include any suitable type of sensor. Various examples of different types of sensors will be described herein. However, it will be understood that the embodiments are not limited to the particular sensors described. Sensor system 120 may include one or more vehicle sensors 121. Vehicle sensor(s) 121 may detect, determine, sense, or acquire in a combination thereof information about vehicle 100 itself. In one or more arrangements, vehicle sensor(s) 121 may be configured to detect, sense, or acquire in a combination thereof position and orientation changes of vehicle 100, such as, for example, based on inertial acceleration. In one or more arrangements, vehicle sensor(s) 121 may include one or more accelerometers, one or more gyroscopes, an inertial measurement unit (IMU), a dead-reckoning system, a global navigation satellite system (GNSS), a global positioning system (GPS), a navigation system 147, other suitable sensors, or any combination thereof. Vehicle sensor(s) 121 may be configured to detect, sense, or acquire in a combination thereof one or more characteristics of vehicle 100. In one or more arrangements, vehicle sensor(s) 121 may include a speedometer to determine a current speed of vehicle 100.

Alternatively, or in addition, sensor system 120 may include one or more environment sensors 122 configured to acquire, sense, or acquire in a combination thereof driving environment data. “Driving environment data” includes data or information about the external environment in which an autonomous vehicle is located or one or more portions thereof. For example, environment sensor(s) 122 may be configured to detect, quantify, sense, or acquire in any combination thereof obstacles in at least a portion of the external environment of vehicle 100, information/data about such obstacles, or a combination thereof. Such obstacles may be comprised of stationary objects, dynamic objects, or a combination thereof. Environment sensor(s) 122 may be configured to detect, measure, quantify, sense, or acquire in any combination thereof other things in the external environment of vehicle 100, such as, for example, lane markers, signs, traffic lights, traffic signs, lane lines, crosswalks, curbs proximate to vehicle 100, off-road objects, etc.

Various examples of sensors of sensor system 120 will be described herein. The example sensors may be part of the one or more environment sensor(s) 122, the one or more vehicle sensors 121, or both. However, it will be understood that the embodiments are not limited to the particular sensors described.

As an example, in one or more arrangements, sensor system 120 may include one or more radar sensors 123, one or more LIDAR sensors 124, one or more sonar sensors 125, one or more cameras 126, or any combination thereof. In one or more arrangements, camera(s) 126 may be high dynamic range (HDR) cameras or infrared (IR) cameras.

Vehicle 100 may include an input system 130. An “input system” includes any device, component, system, element or arrangement or groups thereof that enable information/data to be entered into a machine. Input system 130 may receive an input from a vehicle passenger (e.g., a driver or a passenger). Vehicle 100 may include an output system 135. An “output system” includes any device, component, or arrangement or groups thereof that enable information/data to be presented to a vehicle passenger (e.g., a person, a vehicle passenger, etc.).

Vehicle 100 may include one or more vehicle systems 140. Various examples of vehicle system(s) 140 are shown in FIG. 1. However, vehicle 100 may include more, fewer, or different vehicle systems. It should be appreciated that although particular vehicle systems are separately defined, each or any of the systems or portions thereof may be otherwise combined or segregated via hardware, software, or a combination thereof within vehicle 100. Vehicle 100 may include a propulsion system 141, a braking system 142, a steering system 143, throttle system 144, a transmission system 145, a signaling system 146, a navigation system 147, other systems, or any combination thereof. Each of these systems may include one or more devices, components, or combinations thereof, now known or later developed.

Navigation system 147 may include one or more devices, applications, or combinations thereof, now known or later developed, configured to determine the geographic location of the vehicle 100, to determine a travel route for vehicle 100, or to determine both. Navigation system 147 may include one or more mapping applications to determine a travel route for vehicle 100. Navigation system 147 may include a global positioning system, a local positioning system, a geolocation system, or any combination thereof.

Processor(s) 110, MR fluid system 170, automated driving module(s) 160, or any combination thereof may be operatively connected to communicate with various aspects of vehicle system(s) 140 or individual components thereof. For example, returning to FIG. 1, processor(s) 110, automated driving module(s) 160, or a combination thereof may be in communication to send or receive information from various aspects of vehicle system(s) 140 to control the movement, speed, maneuvering, heading, direction, etc. of vehicle 100. Processor(s) 110, MR fluid system 170, automated driving module(s) 160, or any combination thereof may control some or all of these vehicle system(s) 140 and, thus, may be partially or fully autonomous.

Processor(s) 110, MR fluid system 170, automated driving module(s) 160, or any combination thereof may be operable to control at least one of the navigation or maneuvering of vehicle 100 by controlling one or more of vehicle systems 140 or components thereof. For instance, when operating in an autonomous mode, processor(s) 110, MR fluid system 170, automated driving module(s) 160, or any combination thereof may control the direction, speed, or both of vehicle 100. Processor(s) 110, MR fluid system 170, automated driving module(s) 160, or any combination thereof may cause vehicle 100 to accelerate (e.g., by increasing the supply of fuel provided to the engine), decelerate (e.g., by decreasing the supply of fuel to the engine, by applying brakes), change direction (e.g., by turning the front two wheels), or perform any combination thereof. As used herein, “cause” or “causing” means to make, force, compel, direct, command, instruct, enable, or in any combination thereof an event or action to occur or at least be in a state where such event or action may occur, either in a direct or indirect manner.

Vehicle 100 may include one or more actuators 150. Actuator(s) 150 may be any element or combination of elements operable to modify, adjust, alter, or in any combination thereof one or more of vehicle systems 140 or components thereof to responsive to receiving signals or other inputs from processor(s) 110, automated driving module(s) 160, or a combination thereof. Any suitable actuator may be used. For instance, actuator(s) 150 may include motors, pneumatic actuators, hydraulic pistons, relays, solenoids, and piezoelectric actuators, just to name a few possibilities.

Vehicle 100 may include one or more modules, at least some of which are described herein. The modules may be implemented as computer-readable program code that, when executed by processor(s) 110, implement one or more of the various processes described herein. One or more of the modules may be a component of processor(s) 110, or one or more of the modules may be executed on or distributed among other processing systems to which processor(s) 110 is operatively connected. The modules may include instructions (e.g., program logic) executable by processor(s) 110. Alternatively, or in addition, data store(s) 115 may contain such instructions.

In one or more arrangements, one or more of the modules described herein may include artificial or computational intelligence elements, e.g., neural network, fuzzy logic, or other machine learning algorithms. Further, in one or more arrangements, one or more of the modules may be distributed among a plurality of the modules described herein. In one or more arrangements, two or more of the modules described herein may be combined into a single module.

Vehicle 100 may include one or more autonomous driving modules 160. Automated driving module(s) 160 may be configured to receive data from sensor system 120 or any other type of system capable of capturing information relating to vehicle 100, the external environment of the vehicle 100, or a combination thereof. In one or more arrangements, automated driving module(s) 160 may use such data to generate one or more driving scene models. Automated driving module(s) 160 may determine position and velocity of vehicle 100. Automated driving module(s) 160 may determine the location of obstacles, obstacles, or other environmental features including traffic signs, trees, shrubs, neighboring vehicles, pedestrians, etc.

Automated driving module(s) 160 may be configured to receive, determine, or in a combination thereof location information for obstacles within the external environment of vehicle 100, which may be used by processor(s) 110, one or more of the modules described herein, or any combination thereof to estimate: a position or orientation of vehicle 100; a vehicle position or orientation in global coordinates based on signals from a plurality of satellites or other geolocation systems; or any other data/signals that could be used to determine a position or orientation of vehicle 100 with respect to its environment for use in either creating a map or determining the position of vehicle 100 in respect to map data.

Automated driving module(s) 160 either independently or in combination with MR fluid system 170 may be configured to determine travel path(s), current autonomous driving maneuvers for vehicle 100, future autonomous driving maneuvers, modifications to current autonomous driving maneuvers, etc. Such determinations by automated driving module(s) 160 may be based on data acquired by sensor system 120, driving scene models, data from any other suitable source such as determinations from sensor data 250, or any combination thereof. In general, automated driving module(s) 160 may function to implement different levels of automation, including advanced driving assistance (ADAS) functions, semi-autonomous functions, and fully autonomous functions. “Driving maneuver” means one or more actions that affect the movement of a vehicle. Examples of driving maneuvers include accelerating, decelerating, braking, turning, moving in a lateral direction of vehicle 100, changing travel lanes, merging into a travel lane, and reversing, just to name a few possibilities. Automated driving module(s) 160 may be configured to implement driving maneuvers. Automated driving module(s) 160 may cause, directly or indirectly, such autonomous driving maneuvers to be implemented. As used herein, “cause” or “causing” means to make, command, instruct, enable, or in any combination thereof an event or action to occur or at least be in a state where such event or action may occur, either in a direct or indirect manner. Automated driving module(s) 160 may be configured to execute various vehicle functions, whether individually or in combination, to transmit data to, receive data from, interact with, or to control vehicle 100 or one or more systems thereof (e.g., one or more of vehicle systems 140).

Detailed embodiments are disclosed herein. However, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-6, but the embodiments are not limited to the illustrated structure or application.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components, or processes described above may be realized in hardware or a combination of hardware and software and may be realized in a centralized fashion in one processing system or in a distributed fashion where different elements are spread across several interconnected processing systems. Any kind of processing system or another apparatus adapted for carrying out the methods described herein is suited. A typical combination of hardware and software may be a processing system with computer-usable program code that, when being loaded and executed, controls the processing system such that it carries out the methods described herein. The systems, components, or processes also may be embedded in a computer-readable storage, such as a computer program product or other data programs storage device, readable by a machine, tangibly embodying a program of instructions executable by the machine to perform methods and processes described herein. These elements also may be embedded in an application product which comprises all the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the foregoing. In the context of this document, a computer-readable storage medium may be any tangible medium that may contain or store a program for use by or in connection with an instruction execution system, apparatus, or device.

Generally, modules as used herein include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object-oriented programming language such as Java™, Smalltalk, C++, or the like and conventional procedural programming languages, such as the “C” programming language or similar programming languages. The program code may execute entirely on a user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

Aspects herein may be embodied in other forms without departing from the spirit or essential attributes thereof. Accordingly, reference should be made to the following claims, rather than to the foregoing specification, as indicating the scope hereof.

What is claimed is:

1. A system, comprising:
a reservoir to store magnetorheological fluid;
a pump;
a heat exchanger; and
a structure having an array of channels to distribute the magnetorheological fluid that provides cooling or electromagnetic interference shielding to a vehicular component.

2. The system of claim 1, wherein the array of channels are comprised of different lengths.

3. The system of claim 1, wherein the array of channels are comprised of different diameters.

4. The system of claim 1, wherein the array of channels are designed to provide maximum cooling toward the center of the structure.

5. The system of claim 1, wherein the array of channels are designed to provide maximum electromagnetic interference shielding toward the center of the structure.

6. The system of claim 1, wherein the vehicular component is a sensor.

7. The system of claim 1, wherein the vehicular component is not an electronic component.

8. A non-transitory computer-readable medium including instructions that when executed by one or more processors cause the one or more processors to:
store magnetorheological fluid;
pump the magnetorheological fluid;
cool the magnetorheological fluid; and
distribute the magnetorheological fluid within an array of channels within a structure to provide cooling or electromagnetic interference shielding to a vehicular component.

9. The non-transitory computer-readable medium of claim 8, wherein the array of channels are comprised of different lengths.

10. The non-transitory computer-readable medium of claim 8, wherein the array of channels are comprised of different diameters.

11. The non-transitory computer-readable medium of claim 8, wherein the array of channels are designed to provide maximum cooling toward the center of the structure.

12. The non-transitory computer-readable medium of claim 8, wherein the array of channels are designed to provide maximum electromagnetic interference shielding toward the center of the structure.

13. The non-transitory computer-readable medium of claim 8, wherein the vehicular component is a sensor.

14. A method, comprising:
storing magnetorheological fluid;
pumping the magnetorheological fluid;
cooling the magnetorheological fluid; and
distributing the magnetorheological fluid within an array of channels within a structure to provide cooling or electromagnetic interference shielding to a vehicular component.

15. The method of claim 14, wherein the array of channels are comprised of different lengths.

16. The method of claim 14, wherein the array of channels are comprised of different diameters.

17. The method of claim 14, wherein the array of channels are designed to provide maximum cooling toward the center of the structure.

18. The method of claim 14, wherein the array of channels are designed to provide maximum electromagnetic interference shielding toward the center of the structure.

19. The method of claim 14, wherein the vehicular component is a sensor.

20. The method of claim 14, wherein the vehicular component is not an electronic component.
